(19) United States
(12) Patent Application Publication
(10) Pub. No.: US 2010/0044416 A1
(43) Pub. Date: Feb. 25, 2010

(54) METHOD OF MANUFACTURING ELECTRONIC COMPONENTS HAVING BUMP

(75) Inventor: Kenta OGAWA, Kanagawa (JP)

Correspondence Address: YOUNG & THOMPSON, 209 Madison Street, Suite 500, Alexandria, VA, 22314, US

(73) Assignee: NEC CORPORATION, Tokyo (JP)

(21) Appl. No.: 12/541,340

(22) Filed: Aug. 14, 2009

(30) Foreign Application Priority Data
Aug. 21, 2008 (JP) 2008-212645

(51) Int. Cl. B23K 1/20; B05D 5/12

(52) U.S. Cl. 228/164; 427/98.4

(57) ABSTRACT

An electronic component manufacturing method including: a step of mounting a bump formation material on a first wiring substrate 100 to melt the bump formation material to form a bump 200 at the wiring substrate 100; a step of pressing a jig onto the bump 200 to form a recessed portion 220 having a front end portion 202; a step of printing a solder paste 420 onto an electrode 410 of a second wiring substrate 400; a step of performing, on the solder paste 420, positional alignment of the bump 200 on the wiring substrate 100 to allow the front end portion 202 to be in contact with the bump; and a step of heating the wiring substrate 400 on which the wiring substrate 100 is mounted, wherein the recessed portion 220 is formed from the bump front end portion 202 toward an outer periphery 230 in contact with the solder paste 420.

The present application is filed on the basis of Japanese Patent Application No. 2008-212645.

### BACKGROUND OF THE INVENTION

The present invention relates to a method of manufacturing electronic components having wiring substrates and bumps and a method of mounting a substrate, and more particularly to a method of manufacturing electronic components having ability to suppress reduction in yield at the time of connection.

As a technology for mounting wiring substrate on which semiconductor chips are mounted onto other substrates such as a mother board, there is provided a technology to provide bumps as an external connection terminal at the wiring substrate to connect the wiring substrate and the other substrate through the bumps.

In Japanese Patent Laid-Open No. 2003-218161, there is disclosed a technology relating to solder bump planarization press-jig for planarizing summit parts of plural solder bumps so that they are flush with each other. In Japanese Patent Laid-Open No. 2007-208080, there is disclosed a technology to allow soldering bumps to be disk-shaped by heating and pressure application treatment. In Japanese Patent Laid-Open No. 10-126047, there is disclosed a technology to press soldering bumps so that there is provided flat plate to ensure the degree of bump edge. The bump edge shape in these prior arts is flat.

In Japanese Patent Laid-Open No. 2001-085558, there is disclosed a technology to form bumps having different height in accordance with warp quantity of the print wiring substrate. In Japanese Patent Laid-Open No. 2001-007132, there is disclosed a technology relating to soldering bump forming apparatus. The bump shape in these prior arts is spherical.

In Japanese Patent Laid-Open No. 2000-243772, there is disclosed a technology to connect conductive ball to an electrode pad by using a silicon template where a recessed portion is formed. In Japanese Patent Laid-Open No. 11-97471, there is disclosed a technology to connect protruding electrodes having a pyramid shape onto respective pad electrodes arranged on a semiconductor chip. In Japanese Patent Laid-Open No. 2004-221502, there is disclosed a technology to embed, by the plating process, a Si template where a pit is formed and an opening portion Au of a plating resist formed thereon, and bonding an electrode (pad) on a chip onto the template by thermal compression or the like. In Japanese Patent Laid-Open No. 9-172021, there is disclosed a technology to supply conductive materials to plural electrodes formed on one surface of the semiconductor device to connect those conductive materials thereto to mold the conductive material so as to have bell shape. Interconnection process in these prior arts, bumps are not melted and the bump shape is conical shape or pyramid shape.

In Japanese Patent Laid-Open No. 11-126863, there is disclosed a technology to allow solder bumps to be pillar terminals in order to obtain high connection reliability. In this technology, the height of the pillar terminals is lager than the maximum diameter Further, description is made as follows: solder is attached to the pillar terminal to connect a wiring substrate onto an attachment substrate through the solder. In this interconnection process, the pillar terminal is not melted Thus, the pillar terminal is expansion/contraction-deformed with respect to warp deformation of the wiring substrate so that connection reliability between the wiring substrate and the attachment substrate is enhanced. In addition, it is disclosed that a recessed portion is provided at the bump bottom surface.

However, the inventor has found out from the technologies described in the above-mentioned literatures that the following problems cannot be solved. In order to allow bumps to be connected to terminals of other electronic components, it is required that the bump material melted by reflow is sufficiently wetted on the terminals of that electronic components. However, there is a possibility that even if the bump is heated so that the temperature becomes equal to melting point or more, the bump is not sufficiently wetted to terminals of other substrate to thereby allow the wiring substrate and other electronic components to undergo unsatisfactory connection so that the yield is lowered. It is proposed to address such phenomenon that the bump front end shape is processed so that there are provided recessed portions to increase the area. However, there takes place the problem that when a closed recessed portion with respect to an outer periphery exists at a contact surface between one terminal and the other terminal in forming such uneven portions, flux is accumulated at that portion so that the flux is not sufficiently delivered up to the outer periphery.

### SUMMARY

In accordance with the present invention, there is provided a method of manufacturing electronic components, including: a step of mounting a bump formation material on a first wiring substrate; a step of melting the bump formation material to form a bump on the first wiring substrate; and a step of pressing a jig onto the formed bump to form a recessed portion having a front end portion, wherein the recessed portion is formed from the front end portion of the bump toward a bump outer periphery at the step of forming the recessed portion having the front end portion of the bump.

Further, in accordance with the present invention, there is provided a method of manufacturing electronic components, including: a step of mounting a bump formation material on a first wiring substrate; a step of forming a bump on the first wiring substrate; a step of pressing a jig onto the formed bump to form a recessed portion having a front end portion; a step of printing solder paste or flux on an electrode of a second wiring substrate; a step of performing, on the electrode of the second wiring substrate where the solder paste is printed, positional alignment of the bump on the first wiring substrate to allow the front end portion to be in contact with the bump; and a step of heating the second wiring substrate on which the first wiring substrate is mounted, wherein the recessed portion is formed from the front end portion toward an outer periphery of the bump in contact with the solder paste.

It have been found that even if a bump is heated at melting point or more, the reason why the bump is not sufficiently wetted on terminals of other electronic components is that thick passivation film such as an oxide film, is formed on a surface of the bump and this passivation film is maintained even after the bump inside is melted.

The following findings have been obtained: flux within solder paste having passivation film removable action is wetted and spread in bump outer peripheral directions through bump front end portions in contact with the solder paste; even if the front end positions of bumps on the same wiring substrate are not completely flush with each other by warp of the wiring substrate and there is an unevenness etc., of a printing height of the solder paste; for this reason, contact area between the bump front end portions and the solder paste varies every bump; flux is not sufficiently wetted and spread toward bump surface in the case of a bump having a small contact area with solder paste; and a passivation film is maintained at the time of melting. In this invention, a recessed portion is formed from the bump front end portion toward the bump outer periphery. Thus wet and spread characteristic of flux at the outer peripheral portion of the hump is improved thus to have ability to suppress the maintenance of the passivation film. Accordingly, lowering of yield when a wiring substrate is connected to other electronic components can be suppressed.

Moreover, it has been found that a bump which has come into contact with solder paste once is away from the solder paste by change of warp shape of a wiring substrate followed by temperature elevation in a heating process at the time of performing connection with other components. In the state where the bump is away from the solder paste, even if the bump is melted there does not take place connection with solder paste. Moreover, since supply of flux from the solder paste toward the bump surface is stopped in that state, when flux components existing on the bump surface is exhausted or volatilized, a passivation film would be formed on the bump surface for a second time. Thereafter, even if there is returned to the state in contact with the solder paste for a second time, there may not take place the case where connection is made by a passivation film which has been re-formed on the surface. In the present invention, since a recessed portion is formed from a bump front end portion toward a bump outer periphery, solder paste and the bump front end portion are caused to be contact with each other so that much flux held on the inner wall surface of the recessed portion. Thereafter, even if there results in the case where the bump and the solder paste are away from each other, since much flux is held on the bump surface, it is possible to suppress reformation of a passivation film onto the bump surface due to exhaust of flux components. Accordingly, lowering of yield when wiring substrate is connected to other electronic components is suppressed.

### BRIEF DESCRIPTION OF THE DRAWINGS

The above and other objects, advantages and features of the present invention will be more apparent from the following description taken in conjunction with the accompanying drawings, in which:

FIGS. 1A and 1B are cross sectional views for explaining an electronic components mounting method according to a first embodiment;

FIG. 2 is a cross sectional view for explaining the electronic components shown in FIG. 1;

FIGS. 3A to 3C are views showing a first example of bump shape, wherein FIG. 3A is a view when the bump is viewed from the side direction, FIG. 3B is a view when the bump is viewed from the upper direction, and FIG. 3C is a view when the bump is viewed from the upper direction in cross section of A-A′ plane of FIG. 3A;

FIGS. 4A to 4D are views showing a second example of bump shape, FIG. 4A is a view when the bump is viewed from the side direction, FIG. 4B is a view showing the bump from the upper direction and FIG. 4C is a view showing the bump from the upper direction in cross section of A-A′ plane of FIG. 4A, and FIG. 4D is a view showing the bump in cross section of B-B′ plane of FIG. 4B;

FIGS. 5A to 5D are views showing a third example of bump shape, wherein FIG. 5A is a view showing the bump from the side direction, FIG. 5B is a view showing the bump from the upper direction, FIG. 5C is a view showing the bump from the upper direction in cross section of A-A′ plane of FIG. 5A, and FIG. 5D is a view showing the bump from the side direction in cross section of B-B′ plane of FIG. 5B;

FIGS. 6A and 6B are cross sectional views showing a manufacturing method of electronic components shown in FIG. 1;

FIGS. 7A, 7B are cross sectional views showing the electronic manufacturing method shown in FIG. 1; FIG. 7C, 7D are views when a front end processing jig shown in FIG. 7B is viewed from the bump processing side, and FIG. 7E is a cross sectional view of C-C′ plane of FIG. 7D;

FIG. 8A is a cross sectional view of electronic components according to a second embodiment of the present invention, and FIG. 8B is a view showing the bump in cross section of A-A′ plane of 8(A);

FIGS. 9A to 9D are schematic diagrams showing cross sectional shape of a groove;

FIG. 10A is a model view showing tissue of crystal of a bump before deformation, and FIG. 10B is a model view showing the tissue of crystal of the bump after the deformation; and

FIG. 11 is a schematic diagram showing an electronic component manufacturing method according to a third embodiment of the present invention.

### DETAILED DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purpose.

x Preferred embodiments of the present invention will now be described with reference to the attached drawings. In all drawings, similar reference numerals are respectively attached to similar components, and the explanation thereof will be omitted as occasion demanded.

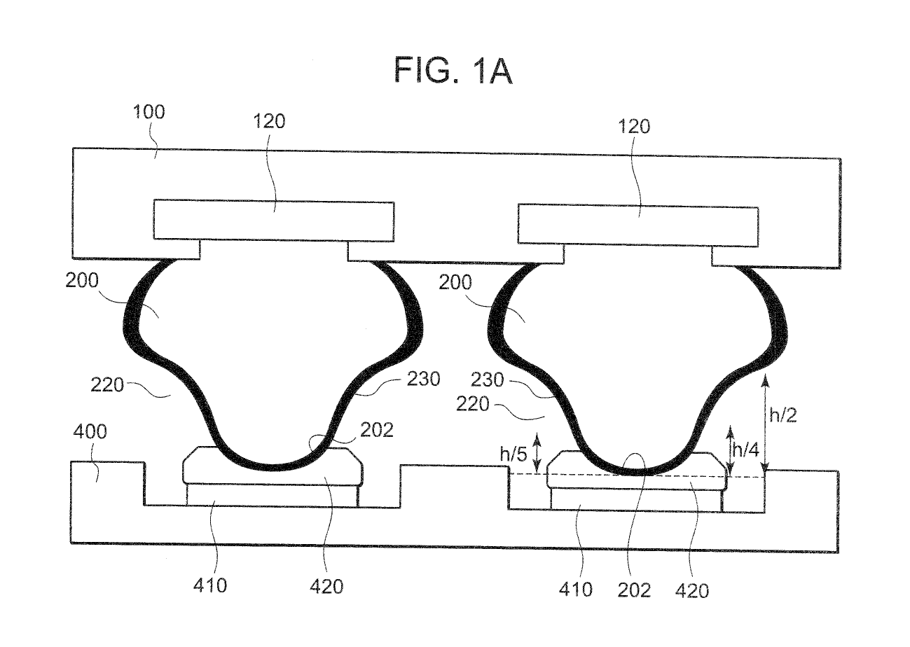

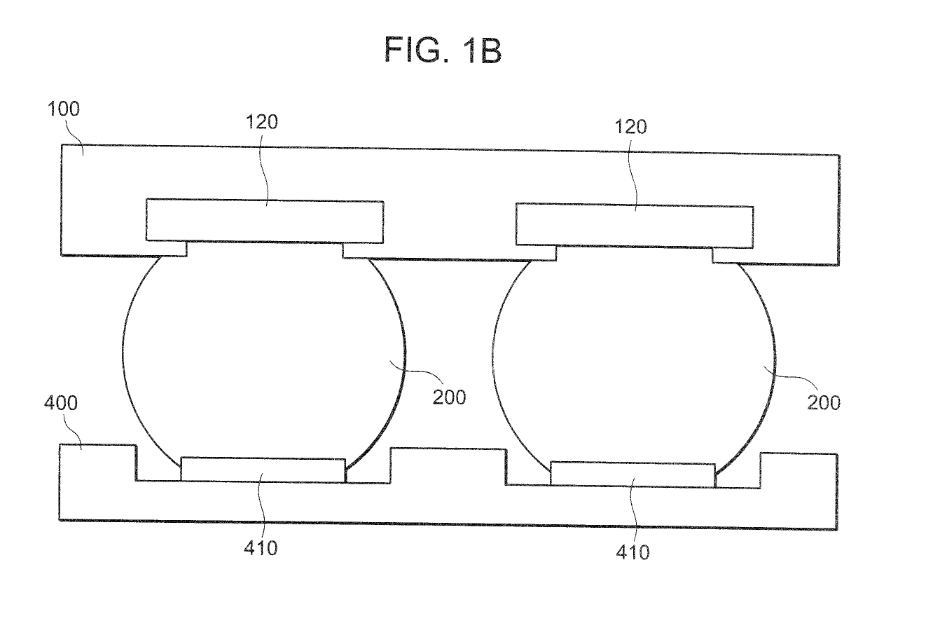

FIGS. 1A and 1B are cross sectional views of an electronic component relating to the present invention. FIG. 1A shows a state where a second wiring substrate 400 has been caused to undergo positioning relative to a first wiring substrate 100 and FIG. 1B is a view showing a state where the second wiring substrate 400 has been caused to undergo positioning thereafter to perform heat treatment so that the first and the second wiring substrate are connected to each other.

The first wiring substrate 100 includes an electrode 120, and a bump 200 is formed on this electrode 120. The second wiring substrate 400 includes an electrode 410, and a solder paste 420 is printed on the electrode. FIG. 1A shows the state of bump 200 of the first wiring substrate 100 and the electrode 410 of the electrode 400 are in contact with each other after positioning is undergone.

When the first wiring substrate 100 and the second wiring substrate 400 are heated in the state where the bump 200 and the solder paste 420 are in contact with each other as shown in FIG. 1A so that after the bump 200 is melted, the first and second wiring substrates 100 and 400 are connected through the bump 200 as shown in FIG. 1B. In FIG 1A, on the surface of the bump 200 before connection in FIG. 1A, there exists a passivation film 210 formed in forming the bump 200 on the first wiring substrate 100.

Before heating for connecting the first and second wiring substrates 100 and 400, the bump 200 and the solder paste 420 are caused to be in contact with each other through a front end portion 202. The solder paste 420 is obtained by holding solder materials formed so as to take a very small particle shape by solvent having viscosity. Flux is included within the solvent. The flux has a function to clean the surface of metals connected, or to remove a passivation film. This flux is wetted and spread over the outer surface of the bump 200 in heating for connecting the first and second wiring substrate 100 and 400. A recessed portion 220 is formed at the bump 200 from the front end portion 202 toward an outer periphery 230. Flux is wetted spread along this recessed portion.

The present invention will now be described with reference to FIGS. 1 to 5.

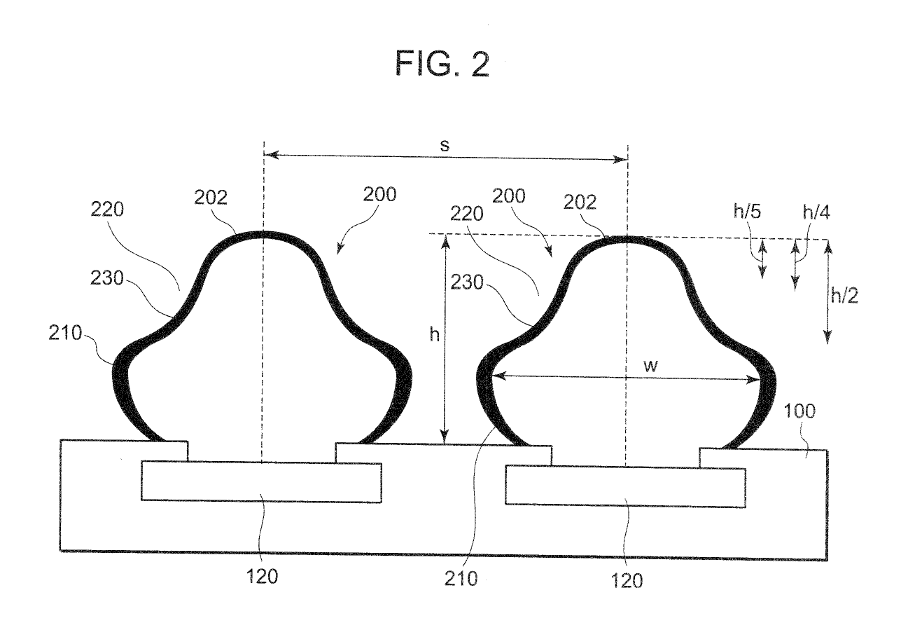

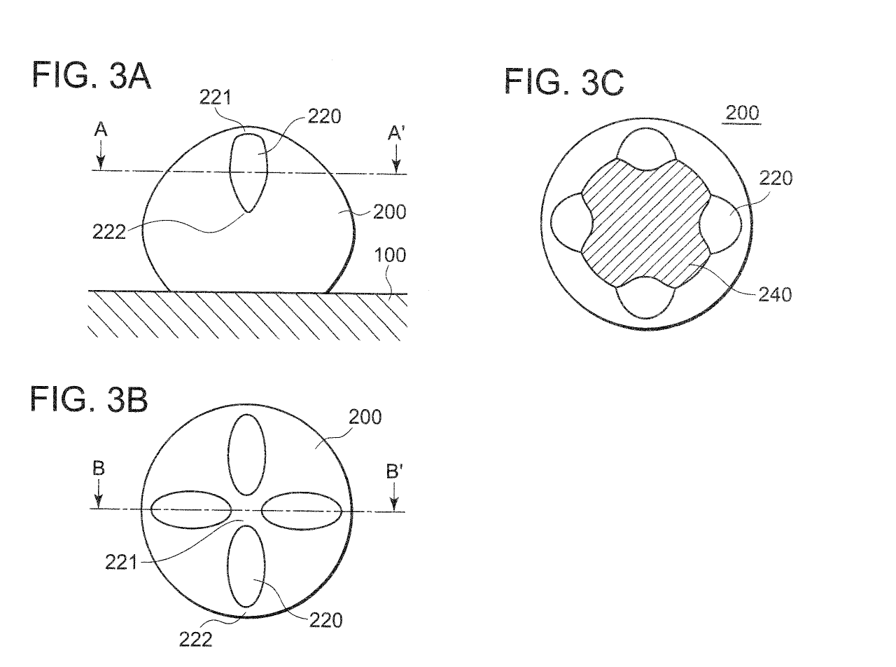

FIG. 2 is a cross sectional view of an electronic component in which the bump 200 is mounted on the first wiring substrate 100 according to a first embodiment. The wiring substrate 100 is a wiring substrate used in, e.g., BGA (Ball Grid Array) However, a wiring substrate used in other mounting structure may be used. FIG. 3A is a view when a first example of the bump 200 is viewed from the side direction of the bump. FIG. 3B is a view when the bump 200 is viewed from the upper direction, and FIG. 3C is a view when the bump 200 is viewed from the upper direction after cut along A-A′ plane of FIG. 2A. The bump cross section of FIG. 1A and FIG. 2 correspond to the cross section of B-B′ plane of FIG. 3B. By melting the bump 200 to connect the melted bump 200 to the electrode 120, the bump is spherical except for the connection surface with the electrode 120. Thereafter, recessed portion 220 is formed by a front end processing jig. For example, in a bump cross sectional surface 240 in FIG. 3C, a shape in a convex direction is formed on the inside of the cross sectional surface 240 in the region where the recessed portion 220 is formed.

In the present embodiment, the bump 200 is, e.g., a solder bump, and is formed in the state with bump formation materials connected to the electrode 120 by mounting and melting solder balls or solder paste as bump formation material on the wiring substrate 100 to solidify melted bump formation material for a second time.

When a template, etc., is not used in melting the bump formation material, the bump 200 takes spherical shape at the time of melting, and is solidified in that shape. The height of the bump and/or the width of the bump of the spherical bump 200 are determined by quantity of the bump formation material and a connection surface area of the electrode 120 etc.

Next, the front end processing jig is pressed onto the surface of the bump 200 placed in solid state, which is connected to the electrode 120 so that the recessed portion 220 is formed. The recessed portion 220 is formed from the bump front end portion 202 toward the bump outer periphery 230.

When it is assumed that the distance from the upper surface of the wiring substrate 100 to the point remotest on the surface of the bump 200, i.e., the bump height is set to h, the maximum width of the bump in the cross section is set to w, the line perpendicular to the electrode 120 and passing through the center of the gravity position of the bump is set to the bump center line, and the distance between center lines of adjacent bumps is set to s, the relation expressed as h≦s holds.

Moreover, when the bump 200 is formed on the electrode 120, there is formed a passivation film 210 consisting of, e.g., residual of flux used in connection or a thick oxide film formed by thermal hysteresis at the time of melting etc.

In the present embodiment, since the front end processing jig is pressed after the passivation film 210 is formed to form the recessed portion, the passivation film 210 is deformed at the recessed portion 220 or in the vicinity thereof by such deformation. Thus, the passivation film 210 is partially broken and the surface area of the bump 200 becomes large. For this reason, the passivation film 210 is partially thinned. Accordingly, the average thickness of the passivation film 210 on the surface of the recessed portion 220 becomes thinner than that of the passivation film 210 of the other portions of the bump, particularly a root portion of the bump 200 which does not undergo an action of bump deformation.

In the present embodiment, the recessed portion 220 is formed from the bump front end portion 202 toward the bump outer periphery 230 In the case where the recessed portion 220 has groove shape, an end portion 221 is formed over the bump front end portion 202 and the other end portion 222 is formed over the outer periphery 230.

In this example, the bump front end portion 202 denotes a region in contact with the solder paste 420.

The bump surface region where the wiring substrate 100 is permitted to be stably in contact with the solder paste when the wiring substrate 100 is mounted on the wiring substrate 400 is a region extending from the position on the bump surface remotest from the wiring substrate 100 on the bump surface to the position of h/5 in terms of the bump height direction. In addition, the bump surface region is a region extending within h/4 at a maximum also there takes place slight differences based on a mounting condition of the wiring substrate 100 onto the wiring substrate 400 etc.

Flux is included within the solder paste 420, and the flux serves to perform cleaning of a connection metal surface or to remove a passivation film. This flux is wetted and spread toward the outer surface of the bump 200 in heating for connection between the first and second wiring substrates 100 and 400. At the bump 200, the recessed portion 220 is formed from the front end portion 202 toward the outer periphery 230. Along the recessed portion, flux is wetted and spread. When flux within the solder paste 420 is wetted and spread to the bump outer periphery 230, the passivation film 210 of the bump outer periphery 230 is apt to be broken. Even in the case where the passivation film 210 of the bump front end portion 202 is not broken, the passivation film 210 at the bump outer periphery 230 is broken so that the bump material within the bump 200 melted by heating in mounting process would be connected to the solder paste 420. The bump outer periphery 230 is a bump surfaced in a region which can be seen from the bump side direction, which cannot be securely in direct contact with the solder paste at the time of mounting the wiring substrate 100 onto the wiring substrate 400.

It should be noted that the bump outer periphery 230 is not direct contact with the solder paste 420 at the time point of mounting of the wiring substrate 100 but undergoes change of bump shape due to melting within the bump in the heating process, warp of the wiring substrate 100 and/or shift in a lateral direction of the wiring substrate 100 by self alignment etc. For this reason there is high possibility that the bump outer periphery 230 comes into contact with the solder paste at the time of melting to remove the passivation film at that portion, thereby making it possible to suppress unsatisfactory connection by the passivation film.

In more concrete terms, flux to the bump surface region corresponding to h/4 or more in terms of the distance in a bump height direction on the wiring substrate 100 side from the position on the surface of the bump 200 remotest from the wiring substrate 100 is wetted and spread so that the bump 200 and the electrode 410 are easily connected to each other. Further, if flux is wetted and spread to the bump surface region corresponding to h/2 or more in terms of the distance in the bump height direction on the wiring substrate 100 side from the position on the surface of the bump 200 remotest from the wiring substrate 100, the bump surface in the region corresponding to half or more in the height direction of the bump 200 is covered by the flux. This is more preferably. For this reason, it is preferable that the other end portion 222 of the recessed portion is located at the position of at least h/4 or more, and it is more preferable that the other end portion 222 is located at the position of h/2 or more.

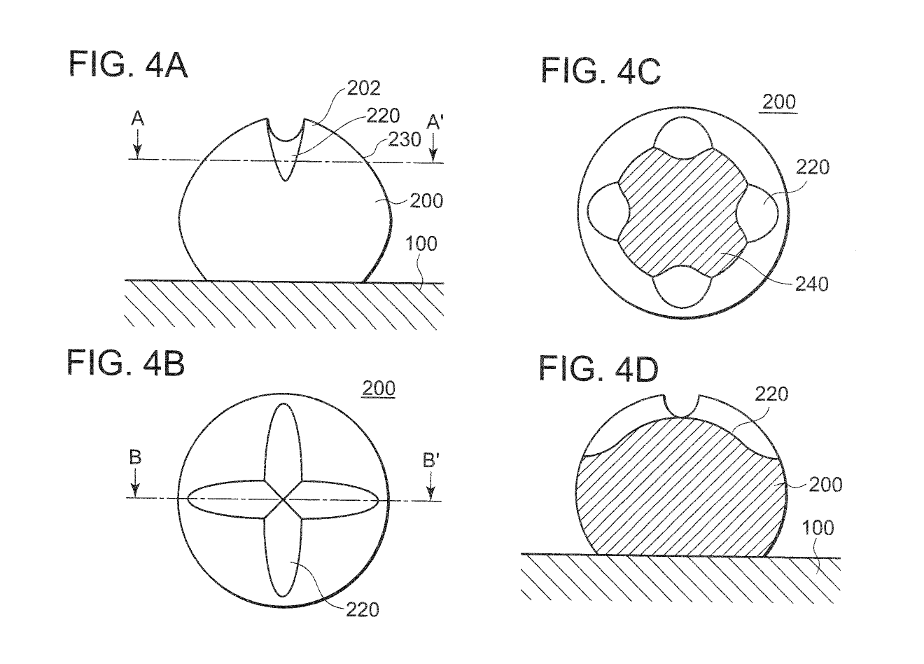

The figures of FIG. 4 are views showing a second example of the bump 200. FIG. 4A is a view when the bump is viewed from the side direction, FIG. 4B is a view when the bump is viewed from the upper direction, FIG. 4C is a view showing the bump from the upper direction in cross section cut along A-A′ plane of FIG. 4A, and FIG. 4D is a view showing that the bump is viewed from the cut surface side when cut along B-B′ plane. The A-A′ plane is a cut plane passing through the bump outer periphery 230. As shown in FIG. 4A, in the second example of the bump 200, the recessed portion 220 is formed so that they are in contact with each other at the bump front end portion 202. Moreover, the bump front end portion 202 is cut into the recessed portions 220 and formed as plural regions. Further, at a bump cross sectional surface 240 in FIG. 4C, convex shape is formed inside the cross sectional surface 240 within the region where the recessed portions are formed.

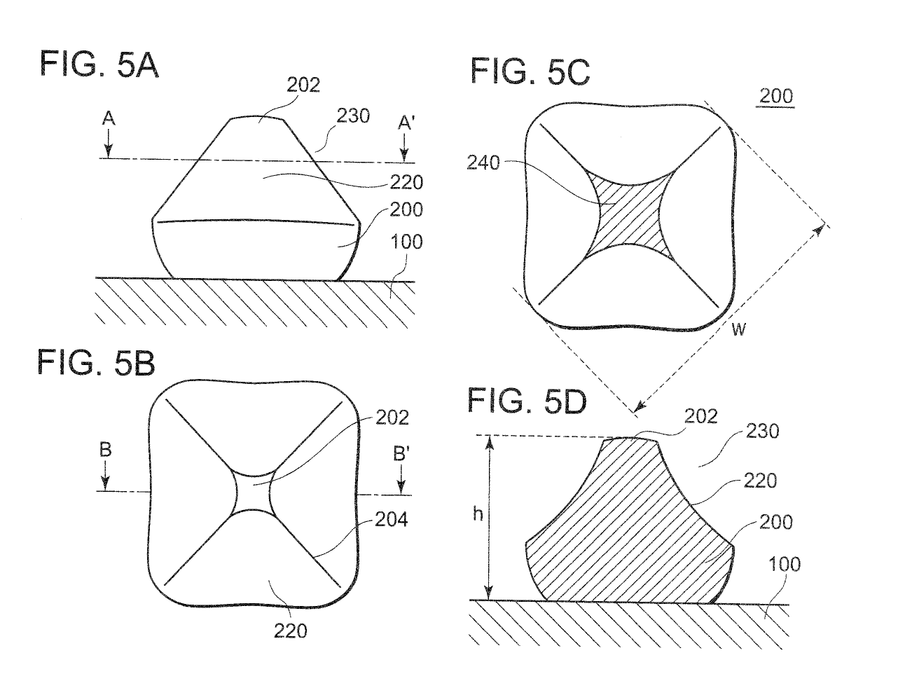

The figures of FIG. 5 are views showing a third example of the bump 200. FIG. 5A is a view when the bump is viewed from the side direction, FIG. 5B is a view when the bump is viewed from the upper direction, FIG. 5C is a view when the bump is viewed from the upper direction cut along A-A′ plan of FIG. 5A, and FIG. 5D is a view when the bump is viewed from the cross sectional surface side cut along B-B′ plan of FIG. 5B. In FIGS. 4A, 4D and FIGS. 5A, 5D, illustration of the electrode 120 on the wiring substrate 100 is omitted.

As shown in FIGS. 5A to 5D in the third example of the bump 200, the recessed portion 220 is formed such that the curvature is caused to be reduced and the width thereof is enlarged. Thus, the bump 200 has the side surface at the front end side, having a polygonal-pyramid shape formed by plural concave surfaces. The respective concave surfaces are connected to each other at a ridgeline 204. In addition, at the bump cross sectional surface 240 in FIG. 5C, there is formed a convex shape inside the cross sectional surface 240 within the region where the recessed portion 220 is formed. While the front end side shape is substantially quadrangular pyramid in FIG. 2D, there may be employed substantially pentagonal pyramid, or substantially triangular pyramid or substantially hexagonal pyramid.

When a volume within the region of the bump front end portion 202 is extremely reduced, the surface area of the bump front end portion 202 directly in contact with the solder paste 420 is reduced. For this reason, when the bump height is expressed as h and the maximum width is expressed as w as shown in FIGS. 5C and 5D, for example, it is desirable that an aspect ratio of the bump h/w is smaller than 1.

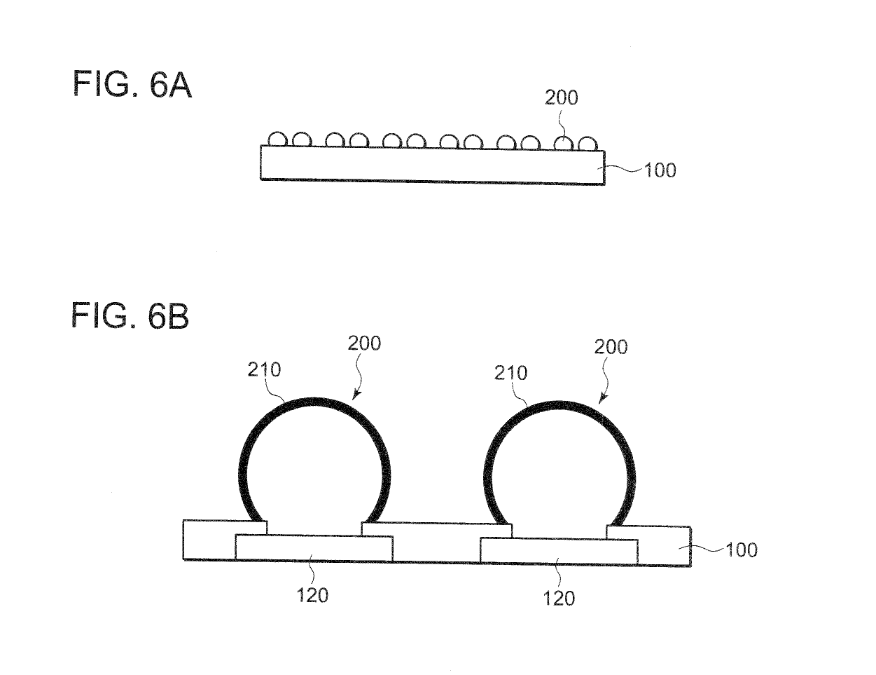

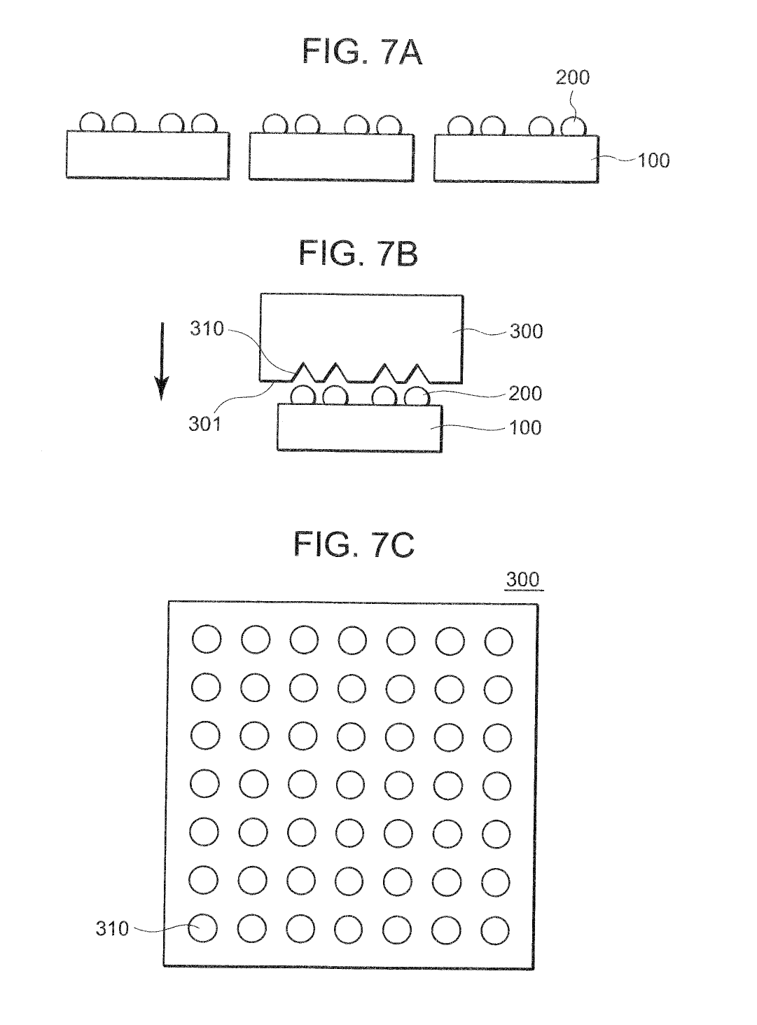

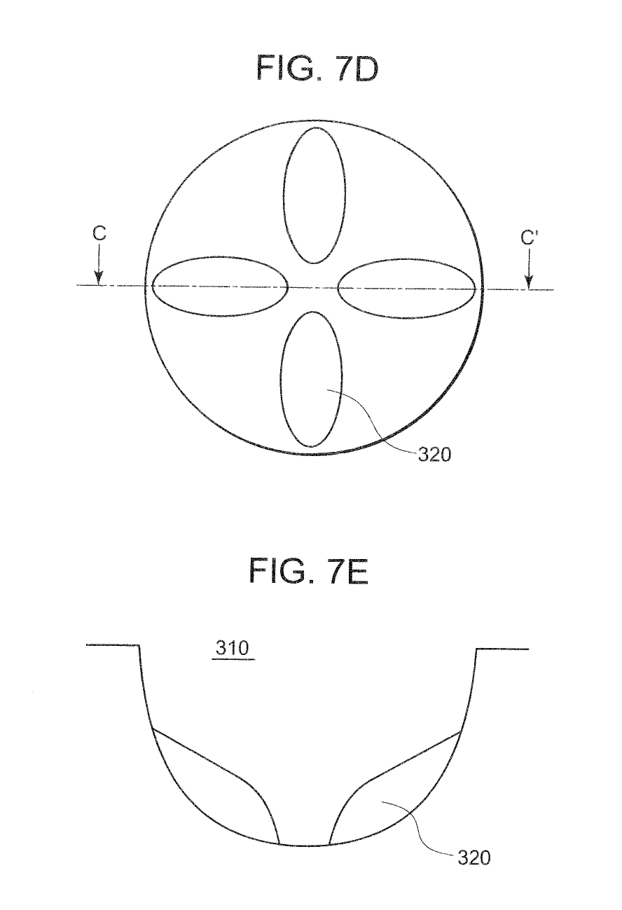

The electronic component manufacturing method of FIG. 1 will now be described. FIGS. 6 and 7 are cross sectional views showing the electronic component manufacturing method shown in FIG. 1. First, as shown in the cross sectional view of FIG. 6A and the cross sectional enlarged view of FIG. 6B, the bump 200 to be connected to the electrode 120 is formed on the wiring substrate 100. In this process step, the wiring substrate 100 is not segmented and plural wiring substrates 100 are connected to each other.

In the case where the bump 200 is formed by using solder balls, flux, not shown, is coated on the electrode 120, and solder balls serving as a bump formation material are mounted on the electrode 120 on which the flux is coated. Further, the solder balls are melted and the melted balls are then solidified so that the bump 200 is formed. Moreover, in the case where the bump 200 is formed by using solder paste, the solder paste is printed by using a squeegee. Thus, the solder paste is provided on the electrode 120. Next, the solder paste is melted thereafter to solidify the melted solder paste so that the bump 200 is formed. It is to be noted that even if any methods described above is used the bump 200 takes a shape such that the surface energy becomes minimum, i.e., spherical shape and the passivation film 210 is formed on the surface of the bump 200.

Next, as shown in the cross sectional view of FIG. 7A, the wiring substrate 100 is segmented. Next, as shown in FIG. 7B, a front end processing jig 300 is pressed onto the bump 200 of the segmented wiring substrate 100. It is preferable that a pressing speed at this time is 1000 mm/sec or less, and it is more preferable that the pressing speed is 50 mm/sec or less. This setting is made to prevent the bump 200 from falling off in the case where a formation position of the bump 200 is slightly shifted to each other, etc., by applying impact stress including a directional component in parallel to the wiring substrate to the bump 200 at the time of processing the front end portion. Thus, the front end portion of the bump 200 is deformed in the solid state so that there results in a form shown in FIG. 1.

Moreover, a temperature in pressing the front end processing jig 300 may fall within the range which does not exceed the melting point of the bump formation material. Further, for example, there is employed an approach to control a temperature of the wiring substrate 100 so that there results in a temperature (K) obtained by multiplying the melting point (K) or a solidus temperature (K) of the bump formation material by 0.75 to 0.95 to thereby having ability to reproduce warp shape of the wiring substrate 100 at the time of a pre-heating process step in connection reflow to other electronic components, and by processing the front end portion thereof in that state to thereby advantageously improve the degree of planarization of the bump front end position at the time of the pre-heating process step. It should be noted that since oxidation, etc., of the bump surface is developed even at a temperature lower than the melting point, controls of an atmosphere and/or a heating time, etc., may be carried out in combination in the case where temperature is high.

In this example, a pressing amount (a pushing amount) of the front end processing jig 300 is controlled on the basis of, e.g., a detection value of a load sensor. Moreover, e.g., DLC (Diamond Like Carbon) coating or nitridization is implemented to the surface of the front end processing jig 300 so that flakes of the bump 200 are made difficult to be attached thereto.

Further, as shown in FIG. 7B, at the front end processing jig 300, a concave shaped portion 310 is formed at the position corresponding to the bump 200 of a jig surface 301. It is not necessarily required that a formation position of the concave shaped portion 310 within the jig surface 301 is caused to correspond to that of the wiring substrate 100 to be processed every kind of wiring substrates, but the concave shaped portion may be arranged in a matrix form at equal intervals as shown in FIG. 7C. Thus, even if wiring substrates of different kinds are employed, when the bump pitch is the same, the front end processing jig 300 may be commonly used. Further, FIG. 7D is an enlarged view when the concave shaped portion 310 is viewed from the jig surface 301 side, and FIG. 7E is a cross sectional view cut along C-C′ surface of FIG. 7D. As shown in these figures, there is formed a convex shaped portion 320 for forming the recessed portion 220 of the bump surface on the surface of the concave shaped portion 310.

It is to be noted that a semiconductor chip (not shown) is mounted on the wiring substrate 100 on the surface opposed to the side where bump 200 exists. Further, a resin layer (not shown) is provided on, e.g., the semiconductor chip so that the semiconductor chip can be protected at the time of processing by the front end processing jig 300.

The semiconductor chip is mounted on the wiring substrate 100 prior to the process step shown in, e.g. FIG. 6A, but the semiconductor chip may be mounted on the wiring substrate 100 after the process step shown in FIG. 6B. In the latter case, the semiconductor chip may be mounted on the wiring substrate 100 prior to segmentation of the wiring substrate 100. Alternately, there may be employed an approach to dispose a wiring substrate in which spherical bumps are formed to carry out processing/deformation processing of the bump 200 prior to interconnection process step to other components.

In either case, since volume change of the bump 200 does not take place in the processing/deformation processing, and the bump is melted for a second time at the interconnection step to other components, the bump shape or the size thereof after connected to other components is fixed irrespective of presence/absence of the front end processing jig 300 or the order of process steps using the front end processing jig 300 Accordingly, in accordance with the present embodiment, there does not take place change of design or connection reliability of other components to be connected to the wiring substrate 100.

Next, the second wiring substrate 400 having the electrode 410 is prepared to carry out printing of the solder paste 420 on the electrode 410. Positioning is performed such that the bump 200 of the wiring substrate 100 is placed on the solder paste over the electrode 410, and the wiring substrate 100 is mounted on the second wiring substrate 400, whereby the state of FIG. 1A is provided. The bump front end portion 202 at this time comes into contact with the solder paste 420.

Next, the wiring substrate 400 in the state of FIG. 1A is caused to undergo, e.g., reflow heating to thereby melt the bump 200 and the solder paste 420, thereafter to solidify these components. Thus, the bump 200 and the solder paste 420 are integrated so that they take a spherical shape for a second time between the electrodes 120 and 410 which are opposed to each other in upper and lower directions, and the electrode 120 and the electrode 410 are connected to each other so that there is provided the state of FIG. 1B. Thus, the wiring substrate 100 is mounted on the second wiring substrate 400.

The advantages/effects of the present embodiment will now be described. In this embodiment, the recessed portion 220 is formed from the front end portion 202 of the bump toward the bump outer periphery 230. When the wiring substrate 100 is mounted on the second wiring substrate 400, the bump front end portion 202 comes into contact with the solder paste. Flux in the solder paste is wetted and spread toward the bump outer periphery 230 through the bump front end portion 202 thus to remove the passivation film 210 at the bump outer periphery 230.

At this time, in the case where there is no recessed portions at the surface of the bump 200, or in the case where even if the recessed portion is formed, the recessed portion is not formed from the bump front end portion 202 toward the bump outer periphery 203 in contact with the solder paste, there are instances where flux may not be sufficiently drawn into the bump periphery.

In the present embodiment, the recessed portion 220 is formed at the bump 200 from the bump front end portion 202 toward the bump outer periphery 203. Thus, the flux is passed from the bump front end portion 202 to the recessed portion 220 by capillary action etc., resulting in enhancing the wet/spreading of the flux toward the bump outer periphery 203. Thus, a sufficient amount of the flux is delivered even in the region with no direct contact with the solder paste. As a result, it is possible to suppress no connection of the passivation film 210 in the state where the passivation film 210 of the surface of the bump 200 is not broken.

Further, shape change of the wiring substrate 100 due to temperature actually takes place. For this reason, in the process from FIG. 1A showing the state where the wiring substrate 100 is mounted on the wiring substrate 400 to FIG. 1B in which the bump 200 is melted so that the connection to the wiring substrate 100 is completed, the bump 200 cannot maintain the contact with the solder paste at all times.

Explanation will now be given in more concrete manner by using FIG. 1A. In practice, a large number of bumps are arranged in left and right directions or in a depth direction of FIG. 1A. FIG. 1A is a view showing a portion thereof.

At an ordinary temperature, the wiring substrate 100 is mounted on the wiring substrate 400. When the wiring substrate 100 is in the state FIG. 1A, in the case where, e.g., the portion in the vicinity of the center of the wiring substrate 100 is warped downward of FIG. 1A, and the peripheral portion is warped upward of FIG. 1A, the front end portion of the bump 200 has similar height distribution. In this case, there may be employed a technique to slightly thrust the wiring substrate 100 toward the wiring substrate 400 side at the time of mounting the wiring substrate 100 to thereby permit the bump front end portions 202 of all bumps 200 to be in contact with the solder paste. At this time, the solder paste is deformed in correspondence with positions in height directions of each bump 200. In this state, flux is delivered to the bump front end portion 202.

Next, in the process where heating is performed to the melting point of the bump 200, when temperature of the wiring substrate 100 is elevated so that, e.g., there takes place a change to warp shape such that the wiring substrate central portion is high and the outer peripheral portion thereof is low, the bump in the vicinity of the wiring substrate 100 is lifted up so that the bump thus deformed is away from the solder past.

Thereafter, when elevation of temperature is developed, the temperature reaches the melting point of the bump formation material, so that melting of each bump is started. Thereafter, As a result of the fact that the bump 200 of the wiring substrate outer peripheral portion which has maintained contact with the solder past is melted or connection to the electrode 420 is developed, the position of the wiring substrate 100 shifts toward the wiring substrate 400. As a result, the bump 200 in the vicinity of the center of the wiring substrate 100 comes into contact with the solder paste for a second time so that connection of the bump to the wiring substrate is also performed. Thus, there results in the state of FIG. 1B, including the bump 200 in the vicinity of the central part of the wiring substrate 100 in which the connection has been performed in a manner delayed.

It is to be noted that the bump 200 lifted up in the process of the elevation of temperature and placed in the state where the bump is away from the solder paste is brought to the condition where there is no delivery of new flux until the bump 200 comes into contact with the solder paste again. Even in this state, removal of the passivation film 210 is developed by the flux which has wet and spread toward the bump 200 where the time the blimp is in contact with the solder paste. The flux is volatilized with time and the reaction is developed so that the exhaust is developed. When its action is lost, a new passivation film 210 is formed on the surface for a second time. Thereafter even if the bump 200 comes into contact with solder paste, the newly formed passivation film 210 prevents or impedes connection.

In the case where no recessed portion is formed at the bump 200, since the amount of flux which has wetted and spread onto the bump surface is small, the exhaust of the flux is developed in a shorter time. In the case where the recessed portion is formed within the region in contact with the solder paste, since a large amount of flux is maintained within the recessed portion, it is possible to elongate a time until the flux is exhausted within the recessed portion. However, in the case where the recessed portion is not formed toward the bump outer periphery 203, the region where the flux is maintained would be limited.

In the present embodiment, the recessed portion 220 is formed from the bump front end portion 202 toward the bump outer periphery 203. Thus, a large amount of flux is maintained within the recessed portion. Even if there takes place the state where the bump floating from the solder paste by warp of the wiring substrate 100 etc., is occurred, there is provided an advantage to suppress the reformation of the passivation film at the bump 200. Further since the held region is formed toward the outer periphery of the bump there can be provided another advantage such that connection when the bump is in contact with the solder paste for a second time becomes easy.

Namely, in the present embodiment, the recessed portion 220 is formed from the bump front end portion 202 toward the bump outer periphery 230. For this reason, the recessed portion 220 serves as a path to effectively delivers flux from the bump front end portion 202 in contact with the solder paste, toward the bump outer periphery 230. Simultaneously, the recessed portion 220 also serves to hold flux. Also after the bump front end is away from the solder paste by warp etc., at the time of mounting, the recessed portion 220 suppresses the passivation film reformation onto the bump surface.

Moreover, since the recessed portion 220 is formed from the front end portion 220 of the bump toward the bump outer periphery 230, it is possible to exhaust volatile gas produced from solvent components of flux toward the outside of the bump 200 or the solder paste at the time of melting. When the bump front end portion 202 is flattened or the recessed portion is provided only at the bump front end portion 202, the volatile gas component is trapped into the bump material, so that that impedes connection or remains the component as a void even if the bump is connected to the solder paste to lower the reliability. In the present invention, the recessed portion 220 acts as a flow-out pass of the volatile component, thus to have ability to suppress lowering of the connectability by the trap of the gas component.

Further, as described above, on the surface of the bump 200, the passivation film 210 is formed by hysteresis at the time of the formation of the wiring substrate 100. Since the melting point of the passivation film 210 is higher than the melting point of the solder constituting the bump 200, solder melted within the passivation film 210 of the bump 200 may be held at the process for mounting the wiring substrate 100 onto the second wiring substrate 400. However, the front end portion 220 of the bump 200 or part in the vicinity thereof is deformed after the formation process step onto the wiring substrate 100 and before there are mounted on the electrode 410 of the second wiring substrate 400. The passivation film 210 is deformed at the front end portion 202 or the part in the vicinity thereof. The passivation film 210 is apt to be broken at the deformed part. Accordingly, it is possible to suppress unsatisfactory connection of the bump 200 to the electrode 410 without breaking the passivation film 210.

Further, the melted solder is caused to undergo shape change such that the surface area thereof becomes minimum, i.e., spherical. As stated above, the recessed portion 220 is formed from the front end portion 220 of the bump toward the bump outer periphery 230. For this reason, after the bump 200 is melted, the bump 200 attempts to perform deformation into spherical shape. Particularly, the recessed portion 220 attempts to perform deformation from a convex shape in the bump internal direction to a convex shape in the bump outside direction. The passivation film 210 is apt to be broken by mechanical action at the time of these deformations. Accordingly, it is possible to further suppress the face that the bump 200 is not connected to the electrode 410 in the state where the passivation film 210 is not broken.

Further, since the recessed portion having the front end portion is formed, or since the formation width of the recessed portion 220 is enlarged as shown in the second example of the bump to allow the front end portion side of the bump 200 to have polygonal-pyramid shape consisting of plural recessed portions, the bump 200 is permitted to have taper shape particularly at the front end side relative to the outer periphery 230. When the wiring substrate 100 is mounted on the second wiring substrate 400 since the weight of the wiring substrate 100 and the semiconductor chip are applied to the bump 200 which has been in contact with the solder paste printed on the electrode 410 of the second wiring substrate 400, the solder paste which supports the bump 200 is thrust in a direction in parallel to the wiring substrate, the wiring substrate 100 is sank to some degree. In the case where the bump shape is taper shape, the quantity of protrusion of the solder paste for supporting the bump 200 becomes large, and as a result, sunk quantity of the wiring substrate 100 becomes large. Accordingly, Even if warp takes place in the wiring substrate 100, it is possible to suppress the bump 200 that is not in contact with the solder paste.

Further, when the bump 200 is caused to have taper shape, the widened quantity in the substrate plane direction is reduced, As a result of the fact that the bump 200 is thrust into the solder paste printed on the electrode 410 when the wiring substrate 100 is mounted on the second wiring substrate 400. Thus, the risk that adjacent bumps 200 are short circuited is small. Accordingly, the quantity of protrusion when the bump 200 of the wiring substrate 100 is mounted on the solder paste coated on the electrode 410 of the second wiring substrate can be increased. Thus, even if there is unevenness of the bump height based on warp of the wiring substrate 100, etc., since high bumps can be mounted on the second wiring substrate 400 in closer thereto, it is possible to securely establish contact between bumps having low height and the solder paste.

Accordingly, the quantity of wetting/spreading of flux is increased, thus making it possible to further suppress the fact that the bump 200 is not connected to the electrode 410 in the state where the passivation film 210 is not broken.

Further, the height of the bump 200, h is smaller than the central interval of plural bumps 200, s or less. For this reason, when the bump 200 is melted and condensed to connect to the electrode 410 of the second wiring substrate 400, it is possible to suppress the fact that the adjacent bumps 200 are short-circuited.

In addition, in the present embodiment, the mounting form after connection to the second wiring substrate 400 is the same as the case where processing deformation of the bump 200 is not performed. For this reason, it is possible to advantageously improve mounting yield without losing reliability after the mounting, i.e., without performing reconfirmation of the reliability, etc.

It is to be noted in this embodiment that there may be employed any material which is melted within the heat resistance temperature of the wiring substrate 100 and other electronic components simultaneously connected, as a material of the bump 200, in place of the solder bump.

Moreover, processing deformation of the bump 200 may be performed at any timing, e.g., either one of a timing after the bump 200 is formed on the wiring substrate 100 or a timing before the wiring substrate 100 is mounted on the second wiring substrate 400.

Further, the plural bumps 200 are not required that shapes of the front end portions 202 are all the same. For example, shapes of the front end portions 202 and the recessed portions 220 of bumps 200 positioned at the central part of the wiring substrate 100 and bumps 200 positioned at the peripheral portion are different from each other.

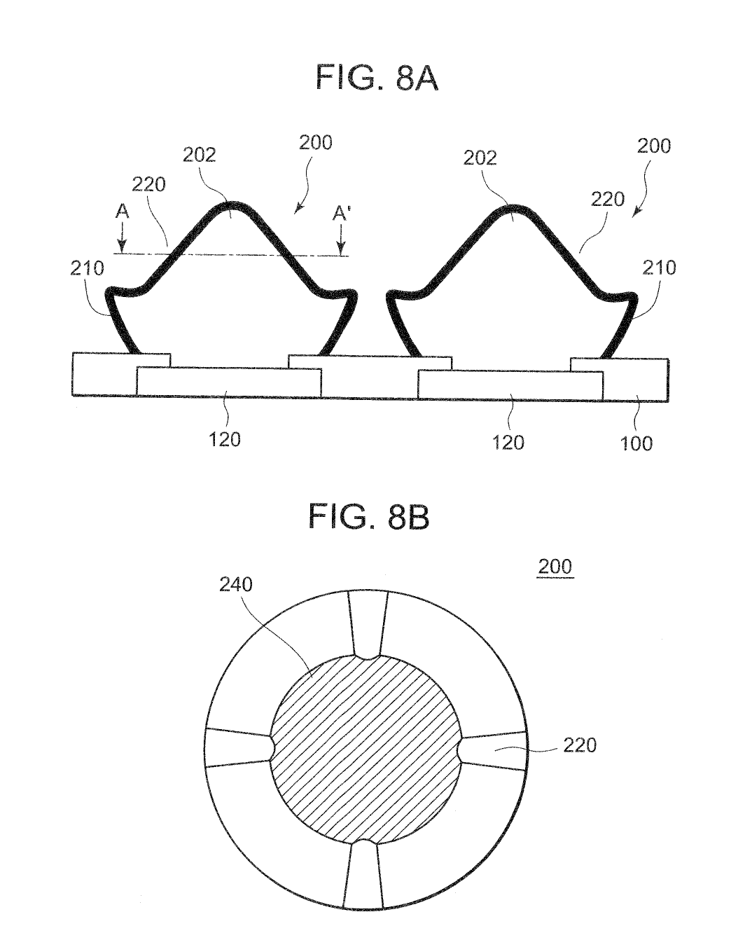

FIG. 8A is a cross sectional view showing the shape of the bump 200 used in electronic components according to a second embodiment of the present invention and FIG. 8B is a view showing the bump 200 viewed from the upper direction in cross section cut along A-A′ surface of FIG. 8A. In the electronic components according to this embodiment, when the bump 200 is connected to the wiring substrate 100, thereafter to press the front end processing jig 300 onto the bump 200 to form the recessed portion 220, a bump height h is caused to be smaller than that at the time of connection. The processing for reducing the bump height h when it is smaller than the bump height h at the time of connection may be carried out by changing shape within the front end processing jig 300. Also, e.g., in the first embodiment, only the convex shaped portion 320 within the concave shaped portion 310 of the front end processing jig 300 is caused to be in contact with the bump 200, there may be a structure to allow the convex shaped portion 320 to be in contact with the internal surface of the concave shaped portion 310 or there may be a structure to increase thrust quantity of the front end processing jig 300 to thereby produce deformation of the whole bump. It is to be noted that it is not necessarily required that the processing for reducing the bump height h when it is smaller than that at the time of connection is performed simultaneously with the formation of the recessed portion 220.

In the present embodiment, the height h of the bump 200 after the front end processing jig is pressed i.e., in the state of FIG. 8A, is smaller than the height h of the bump when the bump formation material is melted to connect the melted bump formation material to the wiring substrate 100 and form the bump, i.e., in the state of FIG. 6B. When the bump 200 so deformed that its height is reduced is heated and melted for a second time, the height h of the bump changes to the bump height h at the time of connection and formation with respect to the wiring substrate 100, As a result of the fact that the shape of the bump returns to spherical shape simultaneously with the melting. Namely, there results in a shape changes such that the bump height h is increased by the melting. By this shape change, there are provided an advantage to hasten to destroy the passivation film and an advantage to allow the bump to be contact with the solder paste at the moment most advantageous to connection, i.e., the state where the bump 200 is molten and the oxide film is mechanically destroyed.

The above described embodiments will now be described in more practical sense.

As state above, in heating process in the mounting process step, warp shape of the wiring substrate 100 changes. As a result, part of the bump 200 is lifted up so that it becomes away from the solder paste onto the electrode 410. Thereafter, when elevation of temperature is developed so that when temperature reaches the melting point of the bump formation material, fusion of respective bumps 200 is started. However, individual bumps 200 have a time difference which is relatively, even if attention is drawn to the adjacent bumps 200.

In the case where the bump height h is not smaller than in the state where the bump 200 is formed on the wiring substrate 100, the bump shapes before and after the melting are both spherical and the bump heights are substantially the same. For this reason, even if the bump 200 placed in lifted up state is melted, the bump remains to be away from the solder paste. Thereafter, other bumps 200 are melted so that the distance between the wiring substrate 100 and the wiring substrate 400 is reduced. As a result, connection cannot be made until the bump 200 comes into contact with the solder paste 420.

In the embodiment of the present invention, since the height of the bump 200 is reduced by processing and deformation by the front end processing jig 300 from spherical shape which is a shape in the melted state, the distance between these electrodes of the wiring substrates 100 and 400 is already close at the state where the wiring substrate 100 is mounted on the second wiring substrate 400. Further, also in the case where the bump 200 in a floating state is melted, the bump returns to spherical shape for a second time by fusion so that there takes place a change such that the bump height is increased, the bump 200 comes into contact with the solder paste on the opposite electrodes 410 at the moment when the bump is melted, i.e., in the state where the bump is most advantageously connected. Accordingly, it is possible that the bump 200 is not connected to the electrode 410 resulting from the unevenness or the change of the bump height by warp, etc., of the wiring substrate 100 and time differences of fusion every bump.

Since the bump height h in spherical shape becomes equal to the value close to the maximum width w of the bump width, setting is made such that h<w is caused to hold in the processing deformation process by the front end processing jig. Thus, the above-mentioned advantages can be expected. Further, it is more desirable that the bump height h is set to a value equal to a value obtained by multiplying the maximum value w of the bump width by 0.8 or less. It is to be noted that when the bump shape is caused to be too oblate, a gap between adjacent bumps becomes narrow. As a result, since short circuiting risk at the time of mounting is increased, it is desirable that the bump height is a value 0.4 times or more larger than the maximum width w of the bump width.

Moreover, when the point remotest in the surface of the bump 200 from the upper surface for wiring substrate 100 is assumed as a bump summit point, the bump summit point exists on a straight line perpendicular to the electrode 120 plane and passing though the central position of the electrode 120 plane when the bump 200 is connected to the wiring substrate 100, when the bump 200 connects to the wiring substrate 100 to be formed. However it is desirable that the position in the substrate plane direction is not changed before and after the processing and deformation. The reason why such an approach is employed is as follows. The positioning at the mounting process step of the wiring substrate 100 becomes difficult or the bump summit point deviates from the printed solder paste 420, thus the contact area with the solder paste 420 becomes small so that the contact with flux becomes unadvantageous.

Moreover, in the present embodiment, as shown in FIG. 8B, cross sectional shape of the recessed portion to be formed on the surface of the bump 200 is caused to be V groove and the groove disposed extending from the front end toward the bump side surface is reached to the maximum point of the bump width w. Thus, there is provided an advantage to more efficiently perform wetting and spreading of flux toward the side surface of the bump 200.

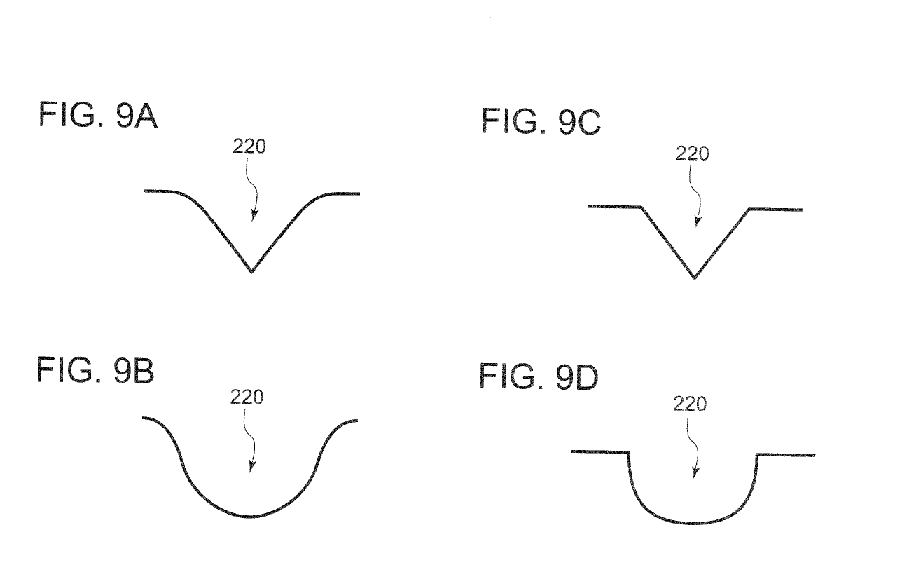

The figures of FIG. 9 are schematic diagrams showing close sectional shapes of the groove 220. In FIG. 8A, the bottom surface of the groove 220 has an acute angle and the boundary portion with the surface of the bump 200 becomes gentle. In FIG. 8B, the groove 220 is arc shape and the boundary portion with the surface of the bump 200 is gentle. In FIG. 8C, the groove 220 at the boundary portion with bottom portion and the boundary portion with the surface of the bump 200 both take acute angles in FIG. 8D, the groove 220 is such that the boundary portion with the surface of the bump 200 is active, but the bottom is gentle. In either case, it is preferable that the width of the groove 220 is larger than the depth of the groove 220, for example, a value falling within the range from twice larger than the depth to four times larger than the depth.

Also in accordance with this embodiment, these can be provided similar effects of advantages as those of the first embodiment. Further, the groove 220 is formed whereby the passivation film 210 shown in the first embodiment becomes thin in the groove 220 so that the passivation film 210 is apt to be broken. Accordingly, it is possible to further suppress the fact that the bump 200 is not connected to the electrode 410 in the state where the passivation film 210 is not broken.

Moreover, in the case where the cross sectional shape of the groove 220 has a shape shown in FIG. 9A or C, the wetting and spreading of flux included in the solder paste on the electrode 410 of the second wiring substance 400 is hastened towards the bump outer periphery by more effective capillary action. Accordingly, the bump 200 is apt to be further connected to the electrode 410.

Further, in the case where the cross sectional shape of the groove 220 has the shape shown in FIG. 9B, solder rubbish attached to the front end processing jig 300 is reduced. Accordingly, the life time of the front end processing jig 300 or cleaning interval is elongated. In addition, stabilized finished quality can be provided.

It is to be noted that the groove shape shown in FIG. 9 can be applied to the first embodiment, and the effect similar to that of the second embodiment can be provided.

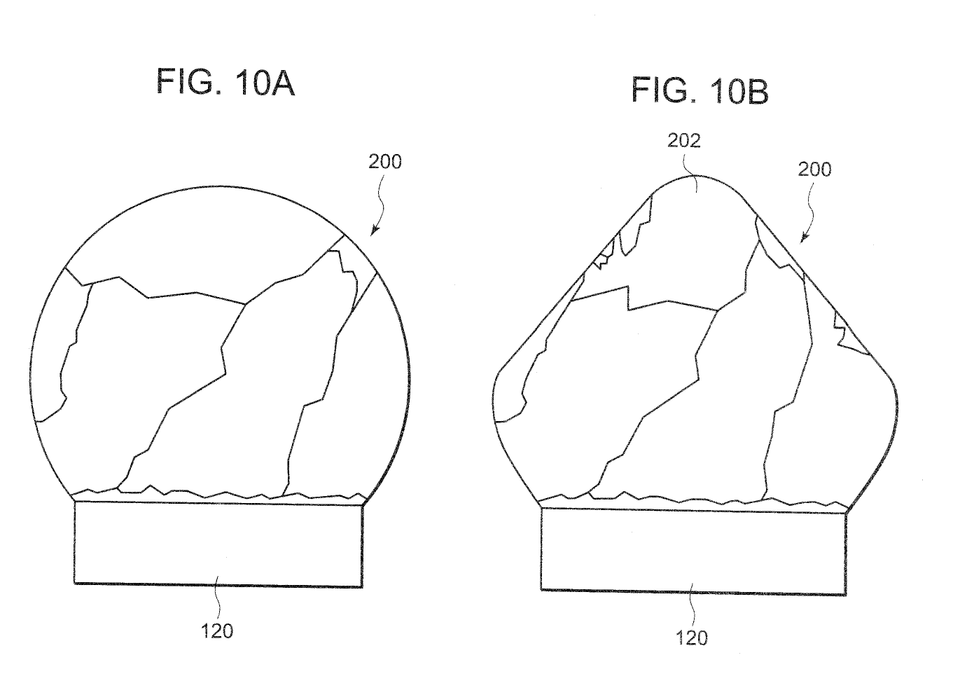

FIG. 10A is a model view showing tissue of the crystal of the bump 200 before the processing and deformation. As stated above, the bump 200 is formed by performing fusion of the crystal tissue to solidify the melted crystal tissue on the electrode 120.

FIG. 10B is a model view showing the tissue of the bump 200 after the processing and deformation. The front end portion of the bump 200 is deformed to constitute the front end portion 202. For this reason, crystal grains become fine as compared to the other portions in the vicinity of the surface of the projection. In particular, in the vicinity of the surface of the projection portion, the diameter of the crystal grains, in a direction of the surface of the projection portion is reduced as compared to the diameter in a direction in parallel to the surface.

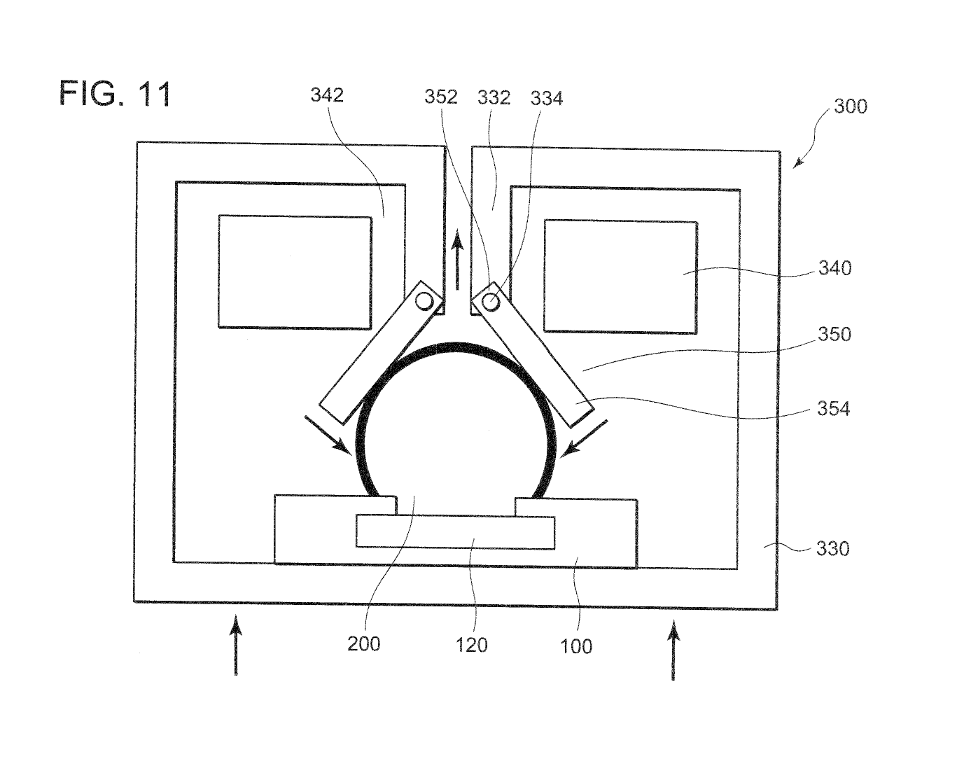

FIG. 11 is a schematic diagram showing an electronic component manufacturing method according to a third embodiment. This electronic component manufacturing method is the same as the electronic component manufacturing method shown in the first embodiment except for the configuration of the front end processing jig 300.

The front end processing jig 300 includes a substrate holding portion 330, a base member 340 and a front end pressing portion 350. The wiring substrate holding portion 330 holds the wiring substrate 100 from the back surface side. The base member 340 is positioned above the surface of the wiring substrate 100 held by the substrate holding portion 330, and includes an opening 342 at the position opposed to the bump 200. Plural extending portions 332 extending from the substrate holding portion 330. The extending portion 332 is admitted into the opening 342 from the side opposed to the bump 200, of the base member 340.

The front end pressing portions 350 are respectively attached to plural extending portions 332. The front end pressing portion 350 is, e.g. a plate-shaped member, and one side 352 is rotatably attached at the front end portion of the extending portion 332 by using a rotation shaft 334. Of the front end pressing portion, the side opposite to one side 350 is an opening end 354. The front end pressing portion 350 at the non-operating time period is opened in a direction away from each other accordingly as it is directed from one side 352 toward the opening end 354. In this state, the opening end 354 is positioned at the outside of the opening 342 when viewed from the plane surface.

When the bump 200 is deformed, a drive mechanism (not shown) shrinks a relative distance between the substrate holding portion 330 and the base member 340. Thus, the bump 200 is inserted into the space encompassed by the front end pressing portion 350 Moreover, the edge of the opening jig 342 of the base member 340 is caused to be in contact with the space between one side 352 and the opening end 354, of the front end pressing portion 350 and pushes the front end pressing portion 350 at the space. Thus, the front end pressing portion 350 rotates about the rotation shaft 334 in a direction such that the opening end 354 is close to another opening end 354. As a result, the bump 200 is pressed by the front end pressing portion. 350, and is then deformed.

Also in accordance with the present embodiment, there can be provided advantages/effects similar to that of the first embodiment. Moreover, the bump 200 is admitted into the space encompassed by the front end pressing portion 350. Thereafter, the bump 200 is put between the front end pressing portions 350 so that it is deformed. For this reason, even in the case where the position of the wiring substrate 100 is shifted in a horizontal direction, this positional shift is adjusted when the front end pressing portions 350 put the bump 200 therebetween, resulting in the deformation of the bump 200.

As stated above, while the preferred embodiments of the present invention have been described with reference to the attached drawings, these embodiments are only illustrated as an example, and various configurations except for the above can be employed.

For example, the wiring substrate 100 may be connected to an electronic component other than the second wiring substrate 400 through the bump 200. The first and second embodiments may be combined together. Further, flux may be printed in place of printing of the solder paste, on the second wiring substrate 400.

It is apparent that the present invention is not limited to the above embodiments, but may be modified and changed without departing from the scope and spirit of the invention.

In addition, in accordance with the preferred embodiments, another aspect of the present invention is disclosed as follows:

an electronic component including:

a first wiring substance; and

a bump connected to the wiring substance and having a front end portion and recessed portion, wherein the recessed portion is formed from the front end portion toward a bump outer periphery.

What is claimed is:

1. A method of manufacturing electronic components, comprising:
forming a bump on a first wiring substrate; and
pressing a jig onto the formed bump to form a recessed portion,
wherein the recessed portion is formed from a front end portion of the bump toward a bump outer periphery.

2. The method of manufacturing electronic components according to claim 1,
wherein the front end portion of the bump is formed on a bump center line.

3. The method of manufacturing electronic components according to claim 1,
wherein the front end portions of the bump are formed in plural.

4. The method of manufacturing electronic components according to claim 1,
wherein the recessed portion is formed at a surface of the bump so as to take an elliptical shape.

5. The method of manufacturing electronic components according to claim 1,
wherein the bump is composed of solder.

6. The method of manufacturing electronic components according to claim 1,
wherein the bump formed on the first wiring substrate is formed by melting a bump formation material after mounting the bump formation material on the first wiring substrate

7. The method of manufacturing electronic components according to claim 6,
wherein the bump formation material is melted so that the bump formed on the first wiring substrate has a spherical shape.

8. The method of manufacturing electronic components according to claim 6,
wherein the pressing the jig onto the formed bump to form a recessed portion includes an allowing a height of a bump after the jig is pressed to be smaller than a height of a bump when the bump formation material is melted to form the bump on the first wiring substrate.

9. The method of manufacturing electronic components according to claim 1,
wherein the jig includes:
a jig surface opposed to the first wiring substrate surface and the bump being put therebetween;
a concave shaped portion disposed in a matrix on the jig surface; and
a pattern having a convex shaped portion formed on an internal surface of the concave shaped portion.

10. The method of manufacturing electronic components according to claim 11
wherein the forming the recessed portion at the front end portion is performed at a temperature having a melting point or less of the bump formation material.

11. The method of manufacturing electronic components according to claim 1,
wherein the recessed portions are formed in plural.

12. The method of manufacturing electronic components according to claim 1,
wherein the recessed portion is formed to be groove-shaped.

13. The method of manufacturing electronic components according to claim 12,
wherein one end of the groove is formed at the front end portion of the bump, and the other end of the groove is formed at the bump outer periphery.

14. The method of manufacturing electronic components according to claim 13,
wherein the other end of the groove is formed at a position of h/4 or more from a position on a bump surface remotest from the first wiring substrate with respect to a distance h from an upper surface of the first wiring substrate up to the position on the bump surface remotest from the first wiring substrate.

15. The method of manufacturing electronic components according to claim 13,
wherein the other end of the groove is formed at a position of h/2 or more from a position on a bump surface remotest from the first wiring substrate with respect to a distance h from an upper surface of the first wiring substrate up to the position on the bump surface remotest from the first wiring substrate.

16. A method of manufacturing electronic components, comprising:
mounting a bump formation material on a first wiring substrate;
melting the bump formation material to form a bump on the first wiring substrate;
pressing a jig onto the formed bump to form a recessed portion;
printing solder paste on an electrode of a second wiring substrate;
performing, on the electrode of the second wiring substrate on which the solder paste is printed, positional alignment of the bump on the first wiring substrate to allow the from end portion to be in contact with the bump; and
heating the second wiring substrate on which the first wiring substrate is mounted,
wherein the recessed portion is formed from the front end portion toward an outer periphery of the bump in contact with the solder paste.

17. The method of manufacturing electronic components according to claim 16,
wherein, the heating the second wiring substrate on which the first wiring substrate is mounted, the bump is formed so that it takes a spherical shape for a second time.

18 A method of manufacturing an electronic component, comprising:
pressing a jig onto a bump of a first wiring substrate on which the bumps in plural are formed to form a recessed portion;
printing solder paste or flux on an electrode of a second wiring substrate;
performing, on the electrode of the second wiring substrate where the solder paste is printed, positional alignment of the bump on the first wiring substrate to allow the front end portion to be in contact with the bump; and
heating the second wiring substrate on which the first wiring substrate is mounted,
wherein the recessed portion is formed from the front end portion of the bump toward an outer periphery in contact with the solder paste.
